(19) United States
(12) Patent Application Publication
(10) Pub. No.: US 2025/0096740 A1
(43) Pub. Date: Mar. 20, 2025

(54) CASCODE POWER AMPLIFICATION CIRCUITS, INCLUDING PROTECTION VOLTAGE CIRCUITS

(71) Applicant: Qorvo US, Inc., Greensboro, NC (US)

(72) Inventors: Baker Scott, San Jose, CA (US); George Maxim, Saratoga, CA (US); Hui Liu, San Diego, CA (US); Stephen James Franck, Felton, CA (US)

(21) Appl. No.: 18/729,627

(22) PCT Filed: Feb. 3, 2023
(86) PCT No.: PCT/US2023/012264

§ 371 Date: Jul. 17, 2024

Related U.S. Application Data
(60) Provisional application No. 63/306,676, filed on Feb. 4, 2022.

(51) Int. Cl. H03F 1/52; H03F 3/213

(52) U.S. Cl. CPC H03F 1/523; H03F 3/213; H03F 2200/426; H03F 2200/451

(57) ABSTRACT

A power amplification circuit (600) includes an amplifier circuit (100) and a circuit (602) protecting the amplifier circuit (100) from destructive voltage. The amplifier circuit includes a first cascode transistor (104(1)) coupled to an output node, a last cascode transistor (104(5)) coupled to a reference voltage node (GND), and one or more cascode transistors (104(2)-104(4)) coupled between the first cascode transistor (104(1)) and the last cascode transistor (104(5)). Circuit protecting the amplifier circuit (100) may include a protection circuit (602) to provide a feedback signal to a bias circuit (606) to reduce the bias voltage on the last cascode transistor (104(5)) and/or a stress control circuit (604) coupled to a control terminal of the first cascode transistor (104(1)) to increase the bias voltage on a control terminal of the first cascode transistor (104(1)) to avoid a destructive voltage.

### FIELD OF THE DISCLOSURE

The technology of the disclosure relates generally to power amplifiers and particularly to cascode power amplifiers.

### BACKGROUND

Mobile wireless communication and data transfer technologies continue to evolve from second generation (2G), third generation (3G), and 4G fourth generation (4G) long-term evolution (LTE) to, most recently, the fifth generation new radio (5G NR) standard. Each generation accesses different frequencies and has increased requirements for bandwidth and range. Since network infrastructures may not be immediately updated in all geographical areas as technologies emerge, a mobile device may encounter networks of different technology generations. Wireless devices must be designed to adapt to these different networks and their respective requirements. Consumers impose additional demands on the most common wireless mobile devices, including longer battery life, smaller device size, and lower cost. Meeting the conflicting demands of evolving technologies and consumers presents many challenges.

### SUMMARY

Aspects disclosed in the detailed description include cascode power amplification circuits, including voltage protection circuits. Related methods of protecting cascode power amplifiers are also disclosed. A power amplification circuit includes an amplifier circuit and a circuit for protecting transistors in the amplifier circuit from a destructive output voltage on an output node. The amplifier circuit includes a series of transistors, including a first cascode transistor coupled to the output node, a last cascode transistor coupled to a reference voltage node (e.g., ground), and one or more middle cascode transistors coupled between the first cascode transistor and the last cascode transistor. The output voltage is distributed across the series of transistors. The output voltage is determined by an input signal on an input terminal coupled to a control terminal of the last cascode transistor and a gain of the last cascode transistor. The circuit protecting the amplifier circuit may include one or both of a protection circuit and a stress control circuit. The protection circuit determines when the output voltage exceeds a threshold and provides a feedback signal to the bias circuit to reduce the bias voltage on at least the last cascode transistor. The stress control circuit includes a variable capacitor and a fixed capacitor coupled in series between the output node and the reference voltage node. The control terminal of the first cascode transistor is coupled to a node between the variable capacitor and the fixed capacitor. As the output voltage increases, the stress control circuit can increase a bias voltage on the control terminal of the first cascode transistor to “float up” the first cascode transistor to avoid a destructive voltage.

In one exemplary aspect, a power amplification circuit is disclosed. The power amplification circuit comprises an amplifier circuit comprising a plurality of cascode transistors coupled in a series between an output node and a reference voltage node, the series comprising a last cascode transistor coupled to the reference voltage node and determining a current in the output node. The power amplification circuit comprises a protection circuit configured to generate a feedback signal in response to an output voltage on the output node exceeding a threshold. The power amplification circuit comprises a bias circuit configured to reduce a bias voltage of the last cascode transistor based on the feedback signal.

In another exemplarity aspect, a power amplification circuit comprising an amplifier circuit and a stress control circuit is disclosed. The power amplification circuit comprises an amplifier circuit comprising a plurality of cascode transistors coupled in a series between an output node and a reference voltage node, the series comprising a first cascode transistor coupled to the output node. The power amplification circuit comprises a stress control circuit comprising a variable capacitor and a fixed capacitor coupled in series between the output node and the reference voltage node and configured to increase a bias voltage on the first cascode transistor in response to the output voltage exceeding a threshold. A control terminal of the first cascode transistor is coupled to a node between the variable capacitor and the fixed capacitor

In another exemplary aspect, a power amplification circuit is disclosed. The power amplification circuit comprises an amplifier circuit comprising a plurality of cascode transistors coupled in a series between an output node and a reference voltage node, the series comprising a first cascode transistor coupled to the output node and a last cascode transistor coupled to the reference voltage node, the last cascode transistor determining a current in the output node. The power amplification circuit comprises a protection circuit generating a feedback signal in response to an output voltage on the output node exceeding a first threshold and a bias circuit reducing a bias voltage of the last cascode transistor based on the feedback signal. The power amplification circuit comprises a stress control circuit comprising a variable capacitor and a fixed capacitor coupled in series between the output node and the reference voltage node and increasing a bias voltage on the first cascode transistor in response to the output voltage exceeding a second threshold. A control terminal of the first cascode transistor is coupled to a node between the variable capacitor and the fixed capacitor.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram of a cascode transistor amplifier;

FIG. 2 is a schematic diagram of a power amplification circuit, including an amplifier circuit, a protection circuit, and a bias circuit coupled to the power amplification circuit;

FIG. 3 is a schematic diagram of the cascode transistor amplifier in FIG. 1 and a first example of a stress control circuit;

FIG. 4A is a graph of output voltages of signals on an output node of the cascode transistor amplifier of FIG. 1;

FIG. 4B is a graph of a capacitance of a variable capacitor in the stress control circuit of FIG. 3 in response to the output voltages in FIG. 4A;

FIG. 5 is a schematic diagram of the cascode transistor amplifier in FIG. 1 with a second example of the stress control circuit;

FIG. 6 is a schematic diagram of the power amplification circuit of FIG. 2 and the stress control circuit as shown in FIG. 3; and

FIG. 7 is a schematic diagram of a two-stage power amplification circuit, including the power amplification circuit of claim 6 as a first stage.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Relative terms such as “over” or “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include cascode power amplification circuits, including voltage protection circuits. Related methods of protecting cascode power amplifiers are also disclosed. A power amplification circuit includes an amplifier circuit and a circuit for protecting transistors in the amplifier circuit from a destructive output voltage on an output node. The amplifier circuit includes a series of transistors, including a first cascode transistor coupled to the output node, a last cascode transistor coupled to a reference voltage node (e.g., ground), and one or more middle cascode transistors coupled between the first cascode transistor and the last cascode transistor. The output voltage is distributed across the series of transistors. The output voltage is determined by an input signal on an input terminal coupled to a control terminal of the last cascode transistor and a gain of the last cascode transistor. The circuit protecting the amplifier circuit may include one or both of a protection circuit and a stress control circuit. The protection circuit determines when the output voltage exceeds a threshold and provides a feedback signal to the bias circuit to reduce the bias voltage on at least the last cascode transistor. The stress control circuit includes a variable capacitor and a fixed capacitor coupled in series between the output node and the reference voltage node. The control terminal of the first cascode transistor is coupled to a node between the variable capacitor and the fixed capacitor. As the output voltage increases, the stress control circuit can increase a bias voltage on the control terminal of the first cascode transistor to “float up” the first cascode transistor to avoid a destructive voltage.

Telecommunications networks are not immediately and simultaneously updated in all geographical areas as a new generation of telecommunication technology emerges. Therefore, mobile devices may need to include transmitters and receivers that operate in a variety of networks. In the evolution from second generation (2G) to third generation (3G), fourth generation long-term evolution (4G LTE), and fifth generation new radio (5G NR), the power demands of transmitters in mobile devices has changed. At the same time, the consumer market has continued to demand smaller and cheaper devices. Both the size and cost of power amplifiers in a wireless transmitter can be reduced by transitioning from amplifier circuits with larger and more expensive transistors, such as bipolar junction transistors (BJTs) made of gallium arsenide (GaAs), for example, lower-voltage transistors. As an example, the lower voltage transistors may be silicon transistors, such as field-effect transistors (FETs) (e.g., metal-oxide-semiconductor (MOS) FETs (MOSFETs)). FETs comprise a gate, a first source/drain, and a second source/drain. A bias voltage on the gate controls flow of current between the first source/drain and the second source/drain.

Previous amplifier circuits made with GaAs BJTs require one or a few transistors that can handle large voltages. However, such large voltages would be destructive to the lower voltage transistors. An amplifier circuit can include a plurality of voltage transistors with a lower voltage limit coupled in series between an output node and a reference voltage node to overcome this problem. The output voltage of a cascode amplifier circuit is distributed across multiple transistors, such that voltage stresses to each transistor is reduced, and damage to the individual transistors may be avoided. With this type of amplifier circuit, the output voltage levels needed in each different generation of telecommunication technology may be achieved at a lower cost and in a smaller package.

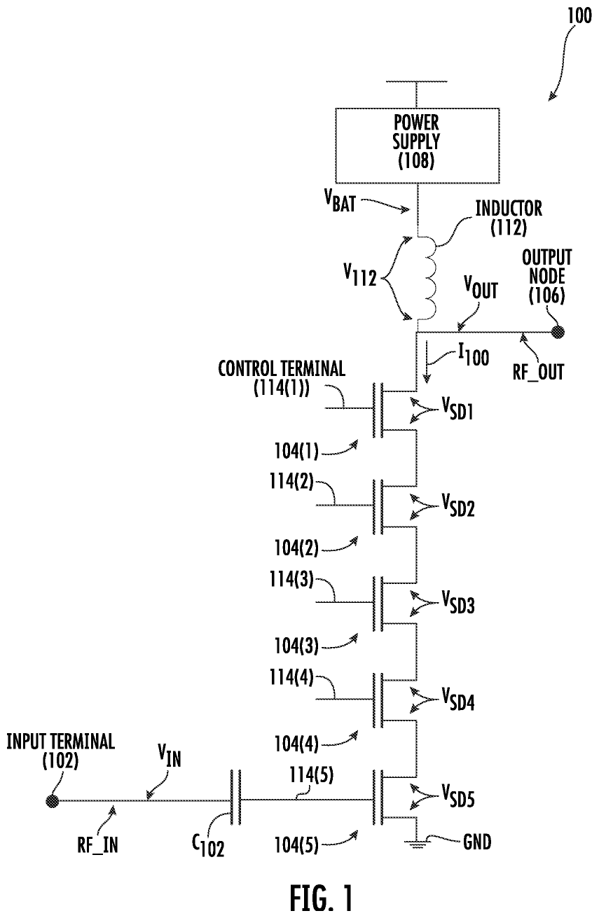

FIG. 1 is an illustration of an example of a cascode amplifier circuit 100 (“amplifier circuit 100”). The amplifier circuit 100 includes an input terminal 102 on which an input radio-frequency (RF) signal RF_IN is received through a capacitor C₁₀₂. The input RF signal RF_IN is an analog signal amplified by cascode transistors 104(1)-104(5) based on a gain of the last cascode transistor 104(5) to generate an RF output signal RF_OUT having an output voltage V_{OUT} on output node 106. The cascode transistors 104(1)-104(5) are coupled in series between the output node 106 and a reference voltage node (e.g., ground voltage node) GND. Although the amplifier circuit 100 in this example includes only five of the cascode transistors 104(1)-104(5), an amplifier circuit in a power amplification circuit as disclosed herein may include fewer or more cascode transistors coupled in series. The amplifier circuit 100 may include cascode transistors 104(1)-104(5) that are all of a first type, such as all N-channel FETs (NFETs) or all P-channel FETs (PFETs). Alternatively, an amplifier circuit of a power amplification circuit as disclosed herein may be a complementary circuit including both NFETs and PFETs.

The amplifier circuit 100 is powered by a power supply 108, such as a battery 108 providing a supply voltage V_{BAT}. The amplifier circuit 100 includes an inductor 112 coupled between the power supply 108 and the output node 106. A current I₁₀₀ through the cascode transistors 104(1)-104(5) increases and decreases in response to changes in a voltage V_{IN} on the input terminal 102. Control terminals 114(1)-114(5) (e.g., gates) of the cascode transistors 104(1)-104(5) are biased to keep the cascode transistors 104(1)-104(5) turned on (e.g., in a saturation region) to conduct the current I₁₀₀. An inductor voltage V₁₁₂ is induced across the inductor 112 in response to changes in the current I₁₀₀. Thus, the output voltage V_{OUT} on the output node 106 is equal to the supply voltage V_{BAT} plus the inductor voltage V₁₁₂ (V_{OUT}=V_{BAT}+V₁₁₂). In this manner, the output voltage V_{OUT} can exceed twice the supply voltage V_{BAT} (i.e., V_{OUT}>2×V_{BAT}). Since the output voltage V_{OUT} is distributed across source-to-drain voltages V_{SD1}-V_{SD5}, in the case of the cascode transistors 104(1)-104(5) comprising FETs, the output voltage V_{OUT} is the total of the source-to-drain voltages V_{SD1}-V_{SD5}. In some cases, the output voltage V_{OUT} may not be equally divided among the source-to-drain voltages V_{SD1}-V_{SD5}. Thus, at a peak in magnitude of the output voltage V_{OUT}, a destructive voltage level may be applied across one or more of the cascode transistors 104(1)-104(5).

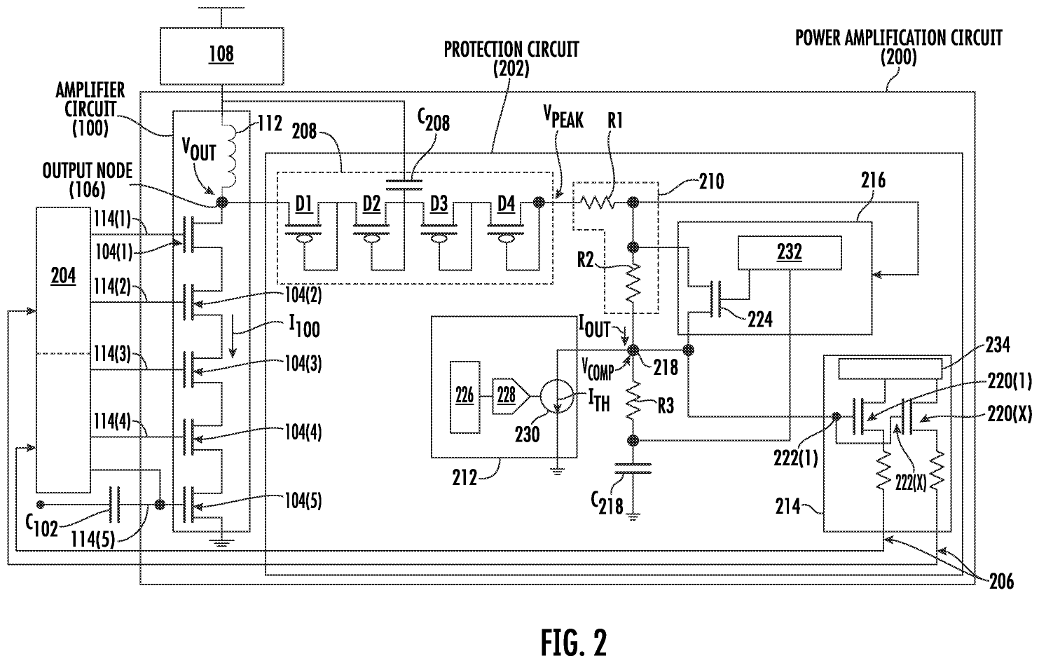

FIGS. 2, 3, and 5-7 are illustrations of examples of power amplification circuits, including circuits that protect the cascode transistors 104(1)-104(5) by adjusting bias voltages on at least one of the control terminals 114(1)-114(5) upon detecting that the output voltage V_{OUT} exceeds a threshold.

FIG. 2 is an illustration of a power amplification circuit 200, including the amplifier circuit 100 of FIG. 1 and a protection circuit 202. Details of the amplifier circuit 100 are shown in FIG. 1. FIG. 2 also includes a bias circuit 204 coupled to the power amplification circuit 200. The bias circuit 204 is an example of a circuit that is coupled to control terminals 114(1)-114(5) to provide bias voltages for controlling the cascode transistors 104(1)-104(5). The protection circuit 202 provides one or more feedback signals 206 to the bias circuit 204 in response to detecting that the output voltage V_{OUT} exceeds a threshold. The protection circuit 202 provides the one or more feedback signals 206 to control the bias circuit 204 to adjust the bias voltages provided to the control terminals 114(1)-114(5). In particular, the one or more feedback signals 206 reduces the bias voltage on at least the control terminal 114(5). In some examples, the one or more feedback signals 206 cause other control terminals 114(1)-114(4), such as the control terminal 114(4), to also be adjusted. Providing feedback to adjust the bias voltage(s) on one or more of the control terminals 114(1)-114(5) reduces the current I₁₀₀ through the amplifier circuit 100, which reduces the possibility of destructive voltages being applied to the cascode transistors 104(1)-104(5).

Before providing details of each of the features of the protection circuit 202, a brief description of the operation of the protection circuit 202 is provided. The protection circuit 202 includes a peak voltage circuit 208 coupled to the output node 106. The peak voltage circuit 208 generates a peak voltage V_{PEAK}, which indicates a highest magnitude of the output voltage V_{OUT}. The peak voltage V_{PEAK} is provided to a voltage-to-current circuit 210 that generates an output current I_{OUT} based on the peak voltage V_{PEAK}. The protection circuit 202 also includes a threshold current circuit 212 that generates a threshold current I_{TH} based on a threshold value. The output current I_{OUT} is compared to the threshold current I_{TH} to determine whether the output voltage V_{OUT} is above a desired (i.e., threshold) level. Specifically, the protection circuit 202 includes a feedback circuit 214 and an acceleration circuit 216 that respond to the output current I_{OUT} being higher than the threshold current I_{TH}. The feedback circuit 214 generates the one or more feedback signals 206. The acceleration circuit 216 increases the responsiveness of the protection circuit 202, so the feedback circuit 214 will respond more quickly and/or to a stronger degree when, for example, the output current I_{OUT} is significantly higher than the threshold current I_{TH}. The features of the protection circuit 202 and their individual operation details are described further below.

The peak voltage circuit 208 includes diodes D1-D4 coupled in series with the anode of the first diode D1 coupled to the output node 106 and the cathode of the last diode D4 coupled to the voltage-to-current circuit 210. The peak voltage circuit 208 also includes a capacitor C₂₀₈ with one terminal coupled to the power supply 108. The other terminal of the capacitor C₂₀₈ is coupled to the cathode of diode D2 and the anode of diode D3. The peak voltage V_{PEAK} is a voltage on the cathode of the last diode D4. The peak voltage V_{PEAK} provided to the voltage-to-current circuit 210 is lower than the actual output voltage V_{OUT} due to voltage drops across the diodes D1-D4 but is based on the output voltage V_{OUT}. In some examples, the diodes D1-D4 are MOS diodes (e.g., P-channel MOS diodes).

The voltage-to-current circuit 210 includes a first resistor R1 in series with a second resistor R2. The first resistor R1 may be much larger than the second resistor R2, the same size, or smaller than the second resistor R2. The voltage-to-current circuit 210 generates the output current I_{OUT} on a comparison node 218 based on the peak voltage V_{PEAK}. The output current I_{OUT} may be proportional to the peak voltage V_{PEAK}. In some examples, the output current I_{OUT} is determined by a difference in voltage between the peak voltage V_{PEAK} and a voltage V_{COMP} on the comparison node 218 and also on the total resistance of the resistors R1 and R2. In this way, the magnitude of the output current I_{OUT} on the comparison node 218 corresponds to the magnitude of the peak voltage V_{PEAK} and, therefore, corresponds to the output voltage V_{OUT}.

The threshold current circuit 212 conducts a threshold current I_{TH} that corresponds in magnitude to the output current I_{OUT} generated when the output voltage V_{OUT} has reached a desired maximum. Beyond the desired maximum of the output voltage V_{OUT}, destructive voltages may be applied to the cascode transistors 104(1)-104(5). In other words, if the output current I_{OUT} is greater than the threshold current I_{TH}, the output voltage V_{OUT} may be high enough to cause destructive voltages on at least one of the cascode transistors 104(1)-104(5). In this context, a destructive voltage can cause permanent physical damage. In this example, the threshold current circuit 212 includes a threshold register 226 configured to store the threshold value. The threshold register 226 is coupled to a digital-to-analog converter (DAC) 228 that generates an analog control signal based on the threshold value. The analog control signal controls a current generator circuit 230 to conduct the threshold current I_{TH} from the comparison node 218.

The protection circuit 200 also includes resistor R3 coupled to the comparison node 218 and a capacitor C₂₁₈ coupled between the resistor R3 and the reference voltage node GND. The resistor R3 and the capacitor C₂₁₈ create a zero in the response of the feedback circuit 214. Current through the comparison node 218 that is not conducted through the threshold current circuit 212 may be conducted through the resistor R3 and the capacitor C₂₁₈.

The output current I_{OUT} may be compared to the threshold current I_{TH} to determine whether the output voltage V_{OUT} has exceeded the desired maximum. In addition, when the output current I_{OUT} exceeds the threshold current I_{TH}, the voltage V_{COMP} on the comparison node 218 increases. In this manner, the feedback circuit 214 detects whether the output current I_{OUT} exceeds the threshold current I_{TH}. If an increase of the voltage V_{COMP} is detected by the feedback circuit 214, the feedback circuit 214 generates the one or more feedback signals 206 to the bias circuit 204 to reduce the bias voltage(s) on one or more of the control terminals 114(1)-114(5). In more detail, the feedback circuit 214 includes at least one transistor 220(1)-220(X) coupled to a circuit 234, where X is an integer value. In some examples, the integer X may correspond to the number of cascode transistors in the amplifier circuit 100. Thus, in the example of cascode transistors 104(1)-104(5), X may be any integer from 1 to 5. In some examples, the circuit 234 may control a power supplied to the at least one transistor 220(1)-220(X). Gate terminals 222(1)-222(X) of the at least one transistor 220(1)-220(X) may be coupled to the comparison node 218 and receive the voltage V_{COMP}. The voltage V_{COMP} of the comparison node 218 remains at a known level while the output current I_{OUT} is less than or equal to the threshold voltage I_{TH}. If the output current I_{OUT} increases above the threshold voltage I_{TH}, the voltage _{VCOMP} will increase, and the bias voltage(s) on the gate terminals 222(1)-222(X) will increase, which causes the current of the one or more feedback signals 206 provided to the bias circuit 204 to also increase. In response, the bias circuit 204 reduces a bias voltage on the control terminal 114(5) of the last cascode transistor 104(5) and may also reduce a bias voltage on one or more of the cascode transistors 104(1)-104(4).

The acceleration circuit 216 includes a bypass transistor 224 that couples to terminals of the resistor R2 of the voltage-to-current circuit 210 to bypass the resistor R2 when the acceleration circuit 216 detects that the output current I_{OUT} exceeds a predetermined stress level. In some examples, the stress level may be determined by a voltage between the resistors R1 and R2 of the voltage-to-current circuit 210. In some examples, the stress level may be determined by a current through the resistor R3. In this regard, the acceleration circuit 216 may be coupled to the resistor R3 and the capacitor C₂₁₈. The stress level may be indicated by a stress value stored in a register 232. The acceleration circuit 216 may activate the bypass transistor 224 when either the voltage V_{COMP} increases or when the acceleration circuit 216 determines that the output current I_{OUT} is greater than the stress current. In some examples, the acceleration circuit 216 activates the bypass transistor 224 when it is determined that the output current I_{OUT} exceeds the threshold current I_{TH} by a predetermined margin. Activating the bypass transistor 224 reduces a resistance in the voltage-to-current circuit 210, which increases the output current I_{OUT} for a given voltage. A lower resistance between the peak voltage circuit 208 and the comparison node 218 increases the current to the comparison node 218, which increases the speed and/or magnitude of the response by the feedback circuit 214.

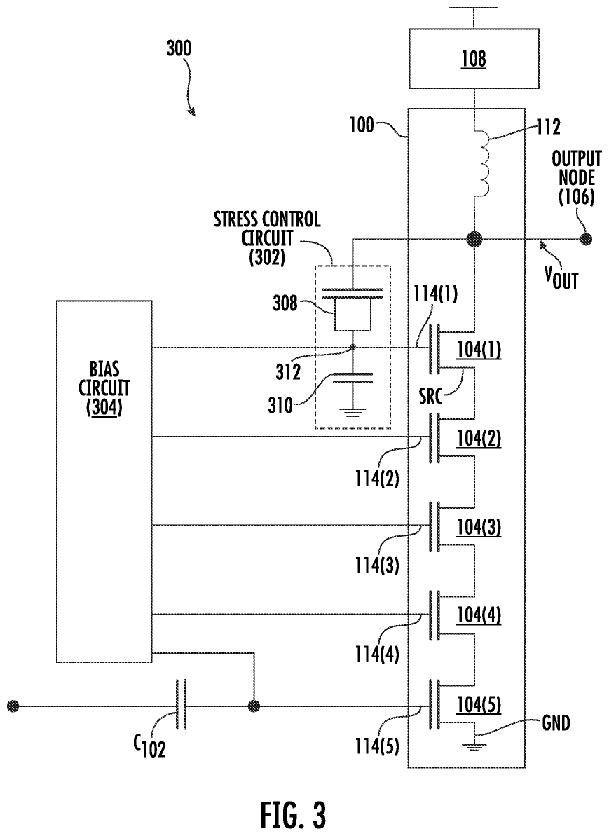

FIG. 3 is an illustration of a power amplification circuit 300, including the amplifier circuit 100 of FIG. 1 and a stress control circuit 302 that protects the cascode transistors 104(1)-104(5) by adjusting bias voltages on at least one of the control terminals 114(1)-114(5) upon detecting that the output voltage V_{OUT} exceeds a threshold. The threshold to which the stress control circuit 302 responds may be the same threshold or a different threshold than the threshold discussed above, to which the feedback circuit 214 responds. FIG. 3 also includes a bias circuit 304 that provides bias voltages for controlling the cascode transistors 104(1)-104(5). The stress control circuit 302 adjusts the bias voltage on at least one of the control terminals 114(1)-114(5) in response to the output voltage V_{OUT} exceeding a threshold. The stress control circuit 302 includes a variable capacitor 308 and a

fixed capacitor 310 coupled in series between the output node 106 and the reference voltage node GND. The variable capacitor 308 may also be a varactor 308. The control terminal 114(1) of the first cascode transistor 104(1) is coupled to a bias node 312 between the variable capacitor 308 and the fixed capacitor 310. For example, in FIG. 3, the variable capacitor 308 is coupled between the output node 106 and the bias node 312. In addition, in the example shown in FIG. 3, the variable capacitor 308 may be a MOS varactor. The fixed capacitor 310 is coupled between the bias node 312 and the reference voltage node GND. As the output voltage V_{OUT} on the output node 106 increases, the variable capacitor 308 coupled to the output node 106 increases in capacitance. As the variable capacitor 308 increases in capacitance, a ratio of capacitance between the variable capacitor 308 and the fixed capacitor 310 increases, causing a bias voltage at the bias node 312 to increase. The bias node 312 is coupled to the control terminal 114(1) of the first cascode transistor 104(1). In the example in which the first cascode transistor 104(1) is an N-channel MOSFET (NFET), the control terminal 114(1) is a gate 114(1), and the output node 106 is a drain terminal 106. Raising the bias voltage on the gate 114(1) raises the voltage on a source terminal SRC of the NFET cascode transistor 104(1) based on a gate-to-source voltage. Raising the voltages on the gate 114(1) and the source terminal SRC as the drain terminal 106 of the first cascode transistor 104(1) increases is referred to herein as “floating up” the first cascode transistor. By increasing the voltage on the source terminal SRC, the voltage drop from the drain terminal 106 to the source terminal SRC is reduced, which avoids a destructive voltage being applied between the drain terminal 106 and the source terminal SRC of the first cascode transistor 104(1). It should be noted that coupling the cascode transistors 104(1)-104(5) in series comprises, as an example, coupling a source terminal SRC of a first one of the cascode transistors 104(1)-104(5) (e.g., 104(x)) to a drain terminal of a next one of the cascode transistors 104(1)-104(5) (e.g., 104(x−1)) in the series in a first direction and coupling a drain terminal of the first one (104(x)) to the source terminal SRC of a next one of the cascode transistors 104(1)-104(5) (e.g., 104(X+1)) in the series in the opposite direction.

In some examples, the stress control circuit 302 may include a second varactor 308 and a second fixed capacitor 310 coupled in series between the output node 106 and the reference voltage node GND with the control terminal 114(2) coupled to a node between the second variable capacitor 308 and the second fixed capacitor 310 to adjust the bias voltage of the cascode transistor 104(2). Although not shown here, the stress control circuit 302 may also include a signal or signals provided to the bias circuit 304 to prevent the bias circuit 304 from reducing the bias voltage on the control terminal 114(1), and possibly one or more other control terminals 114(2)-114(5), in conflict with the stress control circuit 302.

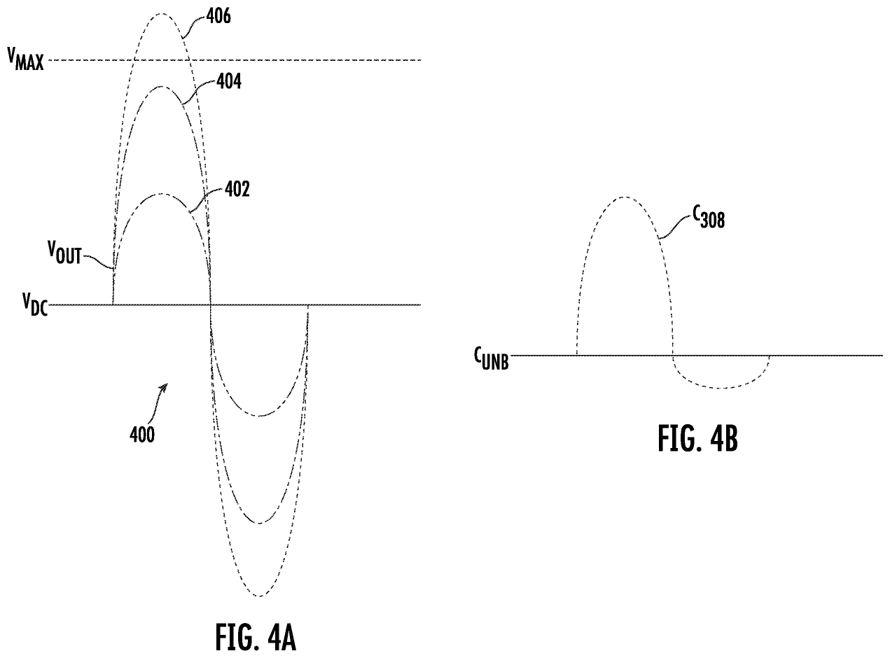

An illustration of the effect of the stress control circuit 302 is provided in FIGS. 4A and 4B. FIG. 4A is a graph 400 illustrating the output voltage V_{OUT} for signals 402, 404, and 406, whose voltages vary in time with respect to a direct current (DC) voltage V_{DC}. A maximum voltage V_{MAX} is also shown in FIG. 4A. If the output voltage V_{OUT} is above the maximum voltage V_{MAX}, the output voltage V_{OUT} will cause a destructive voltage across one or more of the cascode transistors 104(1)-104(5) in the amplifier circuit 100 in FIG. 1. Voltages below the DC voltage V_{DC} do not cause destructive voltages in the amplifier circuit 100. Therefore, when the signals 402, 404, and 406 have low values that cannot cause destructive voltages to the cascode transistors 104(1)-104(5), there is no need to change the capacitance C₃₀₈ with the output voltage V_{OUT} below the DC voltage V_{DC}. As shown, the signals 402 and 404 do not reach a high enough voltage to cause a destructive voltage. However, the signal 406 exceeds the maximum voltage V_{MAX}. The stress control circuit 302 of FIG. 3 responds to increases in the output voltage V_{OUT} by increasing a capacitance of the variable capacitor 308 to raise a bias voltage on the control terminal 114(1) of the first cascode transistor 104(1).

FIG. 4B is an illustration of the capacitance C₃₀₈ of the variable capacitor 308 as it changes relative to an unbiased capacitance C_{UNB} in response to the rise and fall of the signal 406 due to the stress control circuit 302 (not shown here). As shown, the capacitance of the variable capacitor 308 is non-linear, meaning that the response to the output voltage V_{OUT} above the DC voltage V_{DC} differs from the response to the output voltage V_{OUT} below the DC voltage V_{DC}. Specifically, the decrease to the capacitance C₃₀₈ caused by the stress control circuit 302 due to a drop in the signal 406 below the DC voltage V_{DC} is much less than a corresponding increase of the capacitance C₃₀₈ due to a rise in the signal 406 above the DC voltage V_{DC}. In this manner, the stress control circuit 302 changes the bias voltage on the first cascode transistor 104(1) as needed and does not change the bias voltage on the first cascode transistor 104(1) when none is needed.

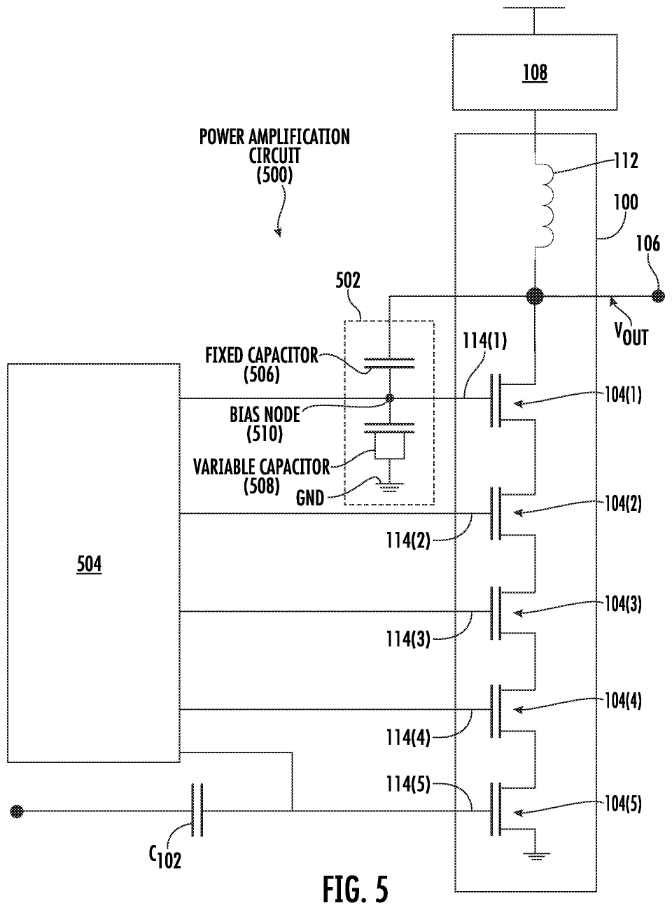

FIG. 5 illustrates an alternative example of a power amplification circuit 500, including the amplifier circuit 100 and a stress control circuit 502. FIG. 5 also includes a bias circuit 504 that provides bias voltages for controlling the cascode transistors 104(1)-104(5). The stress control circuit 502 adjusts the bias voltage on at least one of the control terminals 114(1)-114(5) in response to the output voltage V_{OUT} exceeding a threshold. The stress control circuit 502 includes a fixed capacitor 506 and a variable capacitor 508 coupled in series between the output node 106 and the reference voltage node GND. The variable capacitor 508 may also be a varactor 508. The control terminal 114(1) of the first cascode transistor 104(1) is coupled to a bias node 510 between the variable capacitor 508 and the fixed capacitor 506. In the example in FIG. 5, the fixed capacitor 506 is coupled between the output node 106 and the bias node 510. The variable capacitor 508 is coupled between the bias node 510 and the reference voltage node GND. In addition, in the example shown in FIG. 5, the variable capacitor 508 may be a varactor diode. As the output voltage V_{OUT} on the output node 106 increases, raising the bias voltage on the control terminal 114(1), the variable capacitor 508 decreases in capacitance. As the capacitance of the variable capacitor 508 decreases, the ratio of the fixed capacitor 506 and the variable capacitor 508 decreases, and the bias voltage is further increased.

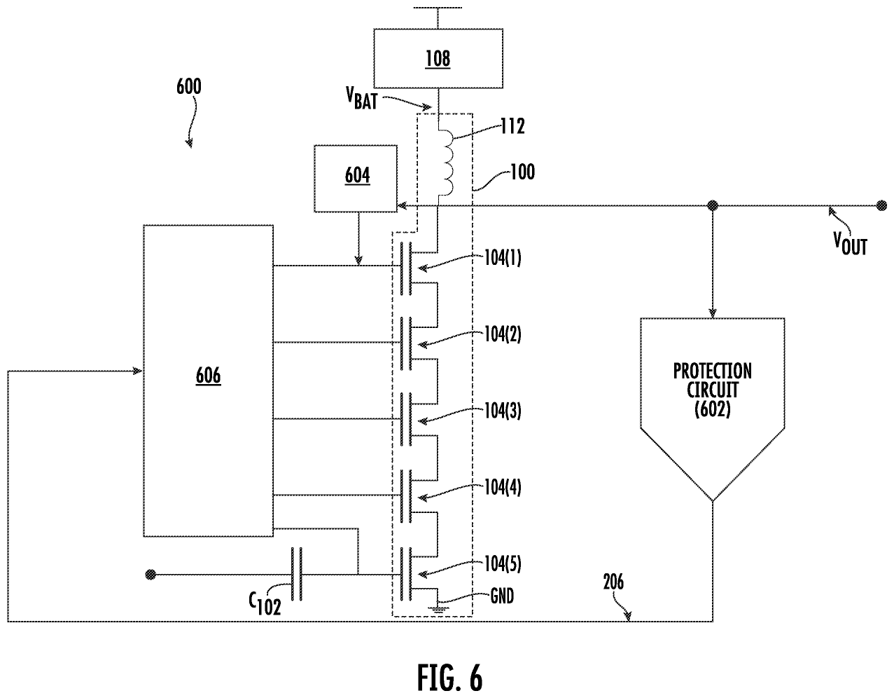

FIG. 6 is an example of the power amplification circuit 600, including the amplifier circuit 100, a protection circuit 602 corresponding to the protection circuit 202 in FIG. 2, and a stress control circuit 604 corresponding to one of the stress control circuits 302 and 502 in FIGS. 3 and 5, respectively. FIG. 6 also includes a bias circuit 606. In response to the output voltage V_{OUT} rising above a voltage at which destructive voltages may be supplied to the cascode transistors 104(1)-104(5), the protection circuit 602 provides a feedback signal 206 that reduces a bias voltage of at least the last cascode transistor 104(5) and the stress control circuit 604 raises a bias voltage of the first cascode transistor 104(1). The feedback circuit 602 reduces the bias voltage of at least the last cascode transistor 104(5) to a bias voltage closer to the reference voltage of the reference voltage node GND (e.g., ground). In contrast, the stress control circuit 604 increases the bias voltage of at least the first cascode transistor 104(1) to a level closer to a supply voltage (V_{BAT}).

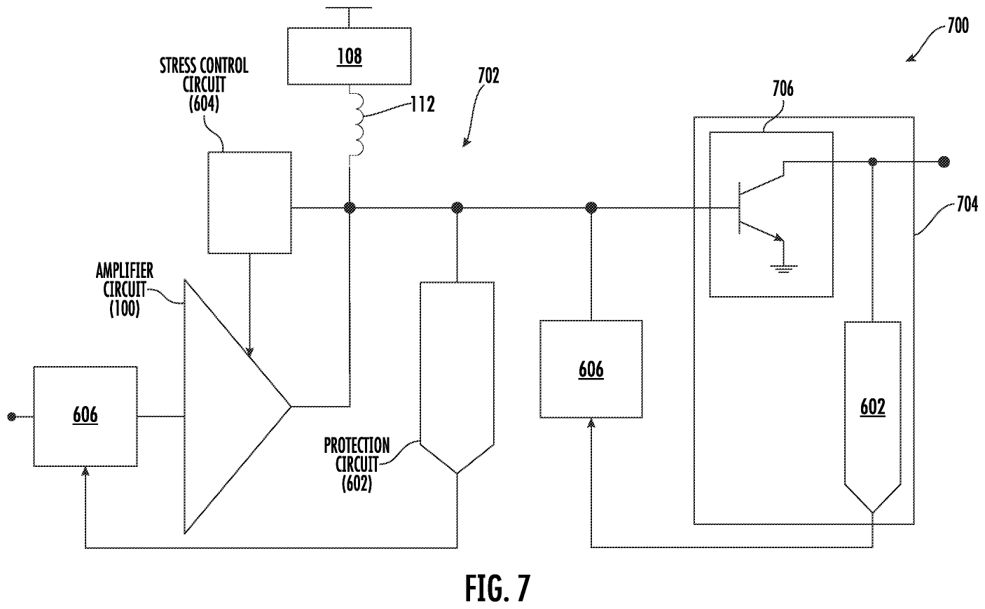

FIG. 7 is an example of a power amplification circuit 700 to show that the power amplification circuit 600 of FIG. 6, including the amplifier circuit 100, the protection circuit 602, and the stress control circuit 604, coupled to the bias circuit 606, may be a first stage 702 of a multi-stage amplifier. FIG. 7 also shows that the power amplification circuit 700 can include a second stage 704. In this example, the second stage 704 includes an amplification stage 706 and the protection circuit 602 coupled to a bias circuit 606. The second stage 704 may also or alternatively include the stress control circuit 604 (corresponding to the stress control circuit 302 in FIG. 3 or the stress control circuit 502 in FIG. 5). Thus, as disclosed herein, cascode amplifiers and amplifier stages may be protected from destructive voltages.

Those skilled in the art will recognize improvements and modifications to the embodiments of the present disclosure. All such improvements and modifications are considered within the scope of the concepts disclosed herein and the claims that follow.

1. A power amplification circuit comprising:
an amplifier circuit comprising a plurality of cascode transistors coupled in a series between an output node and a reference voltage node, the series comprising a last cascode transistor coupled to the reference voltage node and determining a current in the output node;
a protection circuit configured to generate a feedback signal in response to an output voltage on the output node exceeding a threshold the protection circuit comprising:
a voltage-to-current circuit that generates an output current on a comparison node based on the output voltage; and
a threshold current circuit coupled to the comparison node and configured to conduct a threshold current from the comparison node based on the threshold;
wherein the protection circuit generates the feedback signal to the bias circuit in response to the output current to the comparison node exceeding the threshold current; and
a bias circuit configured to reduce a bias voltage on the last cascode transistor based on the feedback signal.

2. The power amplification circuit of claim 1, wherein the plurality of cascode transistors comprises a first cascode transistor coupled to the output node, the last cascode transistor coupled to the reference voltage node, and at least one middle cascode transistor coupled in series between the first cascode transistor and the last cascode transistor.

3. (canceled)

4. The power amplification circuit of claim 2, wherein:
the plurality of cascode transistors are field-effect transistors (FETs); and
the control terminals comprise gates of the FETs.

5. The power amplification circuit of claim 4, wherein each of the plurality of cascode transistors are a first type of FET, wherein the first type of FET is one of an N-channel FET and a P-channel FET.

6. The power amplification circuit of claim 4, wherein:
the first cascode transistor and one of the at least one middle cascode transistor are a first type of FET; and
the last cascode transistor and another one of the at least one middle cascode transistor are a second type of FET.

7. The power amplification circuit of claim 2, wherein the at least one middle cascode transistor further comprises:
a second transistor comprising a first source/drain terminal coupled to the first cascode transistor;
a third transistor comprising a second source/drain terminal coupled to the last cascode transistor; and
one or more transistors in which a first source/drain terminal of each transistor is coupled to a second source/drain terminal of a next transistor in the series, and the one or more transistors are coupled between a second source/drain terminal of the second transistor and a first source/drain terminal of the third transistor.

8. The power amplification circuit of claim 1, wherein the feedback signal to the bias circuit reduces a bias voltage on one of the at least one middle cascode transistor.

9. The power amplification circuit of claim 2, wherein the protection circuit is further coupled to a first source/drain terminal of one of the at least one middle cascode transistor, and the protection circuit further generates a second feedback signal to the bias circuit to reduce a bias on the control terminal of one of the at least one middle cascode transistor.

10. The power amplification circuit of claim 1, the protection circuit further comprising a peak voltage circuit coupled between the output node and the voltage-to-current circuit, wherein:
the peak voltage circuit provides a peak voltage based on the output voltage to the voltage-to-current circuit; and
the output current generated on the comparison node is proportional to the peak voltage.

11. The power amplification circuit of claim 10, wherein:
the amplifier circuit further comprises an inductor comprising a first terminal coupled to a power supply and a second terminal coupled to the output node; and
the peak voltage circuit comprises:
a first diode, a second diode, a third diode, and a fourth diode coupled in series from the output node to the voltage-to-current circuit; and
a first capacitor coupled to the first terminal of the inductor and a node between the second diode and the third diode.

12. The power amplification circuit of claim 1, wherein:
the voltage-to-current circuit comprises a first resistor and a second resistor coupled in series; and
the protection circuit further comprises an acceleration circuit configured to bypass the second resistor to increase the output current on the comparison node in response to the output voltage.

13. The power amplification circuit of claim 1, wherein:
the protection circuit further comprises at least one feedback transistor comprising a gate coupled to the comparison node; and
a voltage on the gate controls the feedback signal.

14. The power amplification circuit of claim 1, wherein the threshold current circuit comprises:
a threshold register configured to store a threshold value;
a digital-to-analog converter (DAC) coupled to the threshold register and generating an analog control signal based on the threshold value; and
a current generator coupled to the comparison node;
wherein the current generator conducts the threshold current from the comparison node based on the analog control signal.

15. The power amplification circuit of claim 1, further comprising:
a third resistor coupled to the comparison node; and
a second capacitor coupled between the third resistor and the reference voltage node.

16. A power amplification circuit comprising:
an amplifier circuit comprising a plurality of cascode transistors coupled in a series between an output node and a reference voltage node, the series comprising a first cascode transistor coupled to the output node;
a stress control circuit comprising a variable capacitor and a fixed capacitor coupled in series between the output node and the reference voltage node and configured to increase a bias voltage on the first cascode transistor in response to the output voltage exceeding a threshold; and
a protection circuit comprising:
a voltage-to-current circuit that generates an output current on a comparison node based on the output voltage; and
a threshold current circuit coupled to the comparison node and configured to conduct a threshold current from the comparison node based on the threshold;
wherein:
a control terminal of the first cascode transistor is coupled to a node between the variable capacitor and the fixed capacitor; and
the protection circuit generates the feedback signal to the bias circuit in response to the output current to the comparison node exceeding the threshold current.

17. The power amplification circuit of claim 16, wherein the plurality of cascode transistors comprises the first cascode transistor coupled to the output node, a last cascode transistor coupled to the reference voltage node, and at least one middle cascode transistor coupled in series between the first cascode transistor and the last cascode transistor.

18. The power amplification circuit of claim 17, wherein:
the variable capacitor comprises a varactor; and
the varactor is coupled between the output node and the control terminal of the first cascode transistor.

19. The power amplification circuit of claim 18, wherein:
the varactor comprises a metal-oxide-semiconductor (MOS) varactor.

20. The power amplification circuit of claim 16, wherein:
the variable capacitor comprises a varactor diode coupled between the control terminal of the first cascode transistor and the reference voltage node.

21. The power amplification circuit of claim 16, the stress control circuit, further comprising:
a second variable capacitor and a second fixed capacitor coupled in series between the output node and the reference voltage node; and
the control terminal of one of the at least one middle cascode transistor is coupled to a node between the second variable capacitor and the second fixed capacitor.

22. A power amplification circuit comprising:
an amplifier circuit comprising a plurality of cascode transistors coupled in a series between an output node and a reference voltage node, the series comprising a first cascode transistor coupled to the output node and a last cascode transistor coupled to the reference voltage node, the last cascode transistor determining a current in the output node;
a protection circuit configured to generate a feedback signal in response to an output voltage on the output node exceeding a first threshold, the protection circuit comprising:
a voltage-to-current circuit that generates an output current on a comparison node based on the output voltage; and
a threshold current circuit coupled to the comparison node and configured to conduct a threshold current from the comparison node based on the threshold;
a bias circuit configured to reduce a bias voltage on the last cascode transistor based on the feedback signal; and
a stress control circuit comprising a variable capacitor and a fixed capacitor coupled in series between the output node and the reference voltage node and increasing a bias voltage on the first cascode transistor in response to the output voltage exceeding a second threshold;
wherein:
a control terminal of the first cascode transistor is coupled to a node between the variable capacitor and the fixed capacitor; and
the protection circuit generates the feedback signal to the bias circuit in response to the output current to the comparison node exceeding the threshold current.
